(19) United States
(12) Patent Application Publication
(10) Pub. No.: US 2015/0276636 A1
(43) Pub. Date: Oct. 1, 2015

(54) DEVICE TO DETECT BATTERY EXPANSION

(71) Applicant: INTEL CORPORATION, SANTA CLARA, CA (US)

(72) Inventors: Naoki MATSUMURA, San Jose, CA (US); Allen HUANG, Beaverton, OR (US); Mike M. NGO, Beaverton, OR (US); Vivek RAMANI, Hillsboro, OR (US); Norman U. ADRE, Beaverton, OR (US)

(73) Assignee: INTEL CORPORATION, SANTA CLARA, CA (US)

(21) Appl. No.: 14/229,567

(22) Filed: Mar. 28, 2014

(51) Int. Cl. G01N 27/02; G01R 31/36

(52) U.S. Cl. CPC G01N 27/02; G01R 31/3644

(57) ABSTRACT

An electronic device may include a panel to cover at least a portion of a battery cell, a first conductive member on the battery cell, and a protection circuit to detect battery expansion based on the first conductive member.

### BACKGROUND

1. Field

Embodiments may relate to a circuit, device or logic to detect expansion of a battery.

2. Background

An electronic device may use a battery (or battery pack) to provide power to components of the electronic device. The battery may need to be charged over time. However, when the battery charge and/or the battery discharge are repeated a number of times, then a battery (or battery cell) may swell (in a z-height) or enlarge. This may be because of gas generation inside of a battery (or a battery pack). If a user continues to use a swollen battery, then a hazardous issue (e.g. explosion, electrolyte leakage, etc.) may occur. System hardware or software may disable the battery charging or the battery discharging after a pre-defined number of charge and discharge cycles. However battery expansion (or swelling) may depend on other factors such as operation temperature, storage condition, charge/discharge profile, etc.

### BRIEF DESCRIPTION OF THE DRAWINGS

Arrangements and embodiments may be described in detail with reference to the following drawings in which like reference numerals refer to like elements and wherein:

FIG. 1 shows an electronic device according to an example arrangement;

FIG. 2 is a side view of an electronic device according to an example embodiment;

FIG. 3 is a view of an electronic device according to an example embodiment;

FIG. 4 is a side view showing battery expansion detection according to an example embodiment;

FIG. 5 is a side view showing battery expansion detection according to an example embodiment; and

FIG. 6 shows an electronic system according to an example embodiment.

### DETAILED DESCRIPTION

In the following detailed description, like numerals and characters may be used to designate identical, corresponding and/or similar components in differing figure drawings. Further, in the detailed description to follow, example sizes/models/values/ranges may be given although embodiments are not limited to the same. Where specific details are set forth in order to describe example embodiments, it should be apparent to one skilled in the art that embodiments may be practiced without these specific details.

A battery cell or a battery pack may be attached to a system or device, such as by adhesive tape. A clearance (or air gap) may be provided between a battery (or battery pack) and a backside panel to protect from battery swelling (or battery expanding).

Embodiments may provide an electrically conductive member (or layer) on a surface of a battery cell/pack and an electrically conductive member (or layer) on a surface of the backside panel. The electrically conductive member (or layer) may be, but is not limited to, a metal sheet, a metal line or a metal deposition layer. Two electrically conductive members (or layers or lines) may be connected to a battery protection circuit (and/or system protection circuit). When a battery expansion (or swelling) occurs, the electrically conductive member (or layer) on a battery (or battery pack) may contact another electrically conductive member (or layer) on the backside panel, which may enable the battery protection circuit to detect an impedance change and the electronic system (or electronic device) may stop further charging or discharging until the battery expansion (or swelling) reaches a safe limit.

In at least one embodiment, the electronic system (or electronic device) may notify a user (via a display or a speaker) to replace a battery rather than stopping a charge or a discharge. The detection may allow the electronic system (or electronic device) to reduce a pre-defined full charge level to a lower safe level (e.g. 60%) as the new full charge capacity and so as to stop further expanding (or swelling).

Embodiments may be provided in an electronic device of in an electronic system. The electronic device may be an apparatus. The electronic device (or system) may be any one of a mobile terminal, a mobile device, a mobile computing platform, a mobile platform, a laptop computer, a tablet, an ultra-mobile personal computer, a mobile Internet device, a smartphone, a personal digital assistant, a display device, a television (TV), etc. Embodiments may be provided in an electronic device of in an electronic system. The electronic device may be an apparatus.

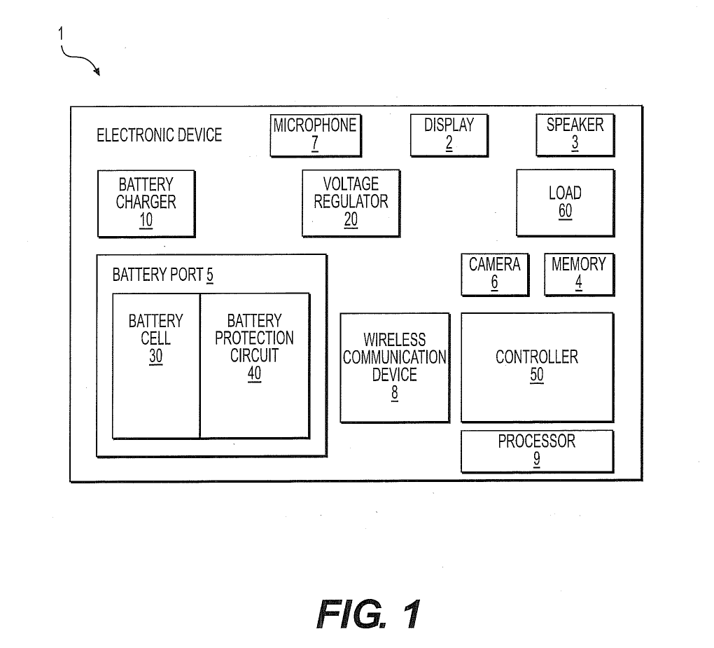

FIG. 1 shows an electronic device according to an example arrangement. Other arrangements and configurations may also be present.

More specifically, FIG. 1 shows an electronic device 1 that may include a battery charger 10, a voltage regulator 20, a battery cell 30 (or battery) in a battery port 5, a battery protection circuit 40 (or protection circuit) in the battery port 5, a controller 50 and a load 60. FIG. 1 also shows the electronic device 1 may include a display 2, a speaker 3, a memory 4, a camera 6, a microphone 7, a wireless communication device 8 and a processor 9. More or less components may also be provided.

FIG. 1 shows the load 60 as being separate from the other components of the electronic device 1. However, the load 60 may include the other components shown in FIG. 1.

The battery pack may include a battery cell and a protection circuit. The battery and the protection circuit may be provided within the battery port 5.

The battery charger 10 may receive power from an external device such as an alternate current/direct current (AC/DC) adapter. The battery charger 10 may supply a voltage to the voltage regulator 20. The voltage regulator 20 may provide a voltage to the load 60, the controller 50 and/or other components, for example. The battery cell 30 and the battery protection circuit 40 may be provided within the battery port 5. Other components may also be provided.

The battery protection circuit (in a battery pack) may function as a short-circuit detection. Another protection circuit may also be provided in addition to the protection circuit in the battery pack. The another protection circuit (or logic) may detect a short circuit.

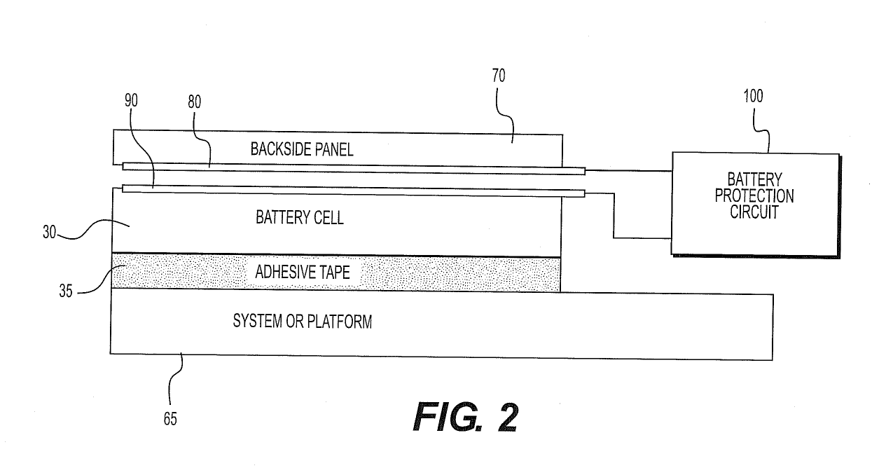

FIG. 2 is a side view of an electronic device according to an example embodiment. Other embodiments and configurations may also be provided.

More specifically, FIG. 2 shows the battery cell 30 within an electronic device. The components shown in FIG. 2 may be provided within an electronic device or an electronic system. As one example, the battery cell 30 may be provided in a battery port on a system or platform 65. The battery port may receive the battery cell (or the battery pack).

A backside panel 70 (or panel) may be part of a body of the electronic device 1 (or an electronic system). In at least one arrangement, the backside panel 70 may be removable by a user so that a user may access the battery cell 30.

A space (such as an air space) may be provided between the backside panel 70 and the battery cell 30. This may allow a small amount of battery swelling (or battery expanding) to occur. However, when the battery cell 30 expands (or swells) too much, then the backside panel 70 may crack or break off and expose the battery cell 30. The battery cell 30 may also rupture.

The battery cell 30 may be any of a number of battery devices, including a single battery cell or a plurality of battery cells. The battery cell (or cells) may include a pouch. In at least one embodiment, the battery cell (or cells) may include a lithium-ion cell (or cells).

The battery cell 30 may be provided within a battery port, for example. The battery port may provide space for the battery cell 30 to be maintained within the body of the electronic device 1 (or an electronic system).

In at least one arrangement, an adhesive tape 35 (or adhesive tape layer) may be provided to maintain the battery cell 30 within the battery port 5. FIG. 2 shows the adhesive tape 35 on the system or platform 65, although the adhesive tape may be provided on other components or other sections of the electronic device 1.

A battery protection circuit 100 (or system protection circuit) may provide protection for the battery and/or other components of the electronic device. The battery protection circuit 100 may be part of an integrated circuit (IC). The battery protection circuit 100 may also be physically connected to a first conductive member 90 on a top surface of the battery cell 30, for example. The battery protection circuit 100 may also be physically connected to a second conductive member 80 on a bottom surface of the backside panel 70, for example.

The battery protection circuit 100 may be part of the battery pack. The battery protection circuit 100 in the battery pack may detect a short circuit and/or protect battery cells from overvoltage, overcurrent, etc. The battery protection circuit 100 may also be a swelling detection circuit (or an expanding detection circuit). The swelling detection circuit (or expanding detection circuit) may be, but is not limited to, a discrete circuit or part of the battery protection circuit in the battery pack.

The first conductive member 90 may be an electrically conductive layer (i.e., a metal layer), an electrically conductive line (i.e., a metal line) and/or an electrically conductive sheet (i.e., a metal sheet) that is provided on a surface of the battery cell 30, for example. Other types of first conductive members may also be provided.

The second conductive member 80 may be an electrically conductive layer (i.e., a metal layer), an electrically conductive line (i.e., a metal line) and/or an electrically conductive sheet (i.e., a metal sheet) provided on a surface of the backside panel 70, for example. Other types of second conductive members may also be provided.

The battery protection circuit 100 (or swelling detection circuit) may detect (or determine) when the second conductive member 80 and the first conductive member 90 contact each other. For example, when the battery cell 30 starts to expand or swell (in an upward manner for FIG. 2), then the battery protection circuit 100 (or swelling detection circuit) may detect (or determine) an electrical connection (or electrical short) between the second conductive member 80 and the first conductive member 90. The protection circuit 100 may detect an electrical short between the first conductive member 90 and the second conductive member 80.

The battery protection circuit 100 (or swelling detection circuit) may also detect (or determine) an impedance change or a resistance change of at least one of the first conductive member 90 and the second conductive member 80.

At this point, the battery protection circuit 100 (or swelling detection circuit) may perform any of a number of operations (or functions) in order to prevent further damage. For example, the battery protection circuit 100 may communicate with the controller 50 to warn of the battery expanding (or battery swelling). A message may be provided on the display of the electronic device, an audio message may be provided from a speaker of the electronic device, and/or power to other components may also be disconnected or even lowered. The electronic device 1 may also communicate with an external terminal/person in order to schedule a battery replacement.

In at least one embodiment, the battery charger (such as the battery charger 70) may decrease a charging of the battery cell when the protection circuit 100 detects the impedance change (or the resistance change).

In at least one embodiment, the protection circuit 100 may decrease charging of the battery cell or discharging of the battery cell when the protection circuit 100 detects a change of at least one of the first conductive member and the second conductive member.

The protection circuit may detect battery cell expansion based on the first conductive member 90. In at least one embodiment, the protection circuit may detect expansion of a battery cell based on a change of at least the first conductive member.

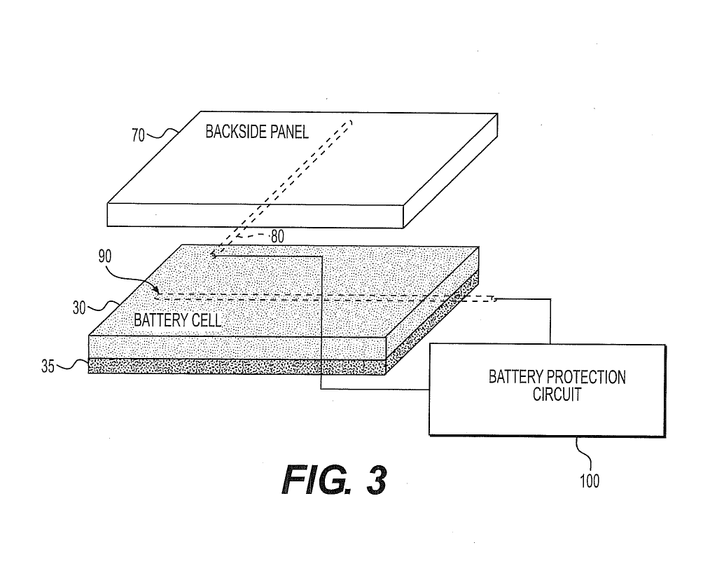

FIG. 3 is a view of an electronic device according to an example embodiment. Other embodiments and configurations may also be provided.

More specifically, FIG. 3 shows similar components as shown in FIG. 2. As can be seen in FIG. 3, the first conductive member 90 (i.e., the first conductive line) may extend in a first direction across a surface (such as a top surface) of the battery cell 30. As can be seen in FIG. 3, the second conductive member 80 (i.e., the second conductive line) may extend in a second direction across a surface (such as a lower surface) of the backside panel 70.

FIG. 3 shows the second direction being substantially perpendicular to the first direction. However, in other embodiments, the second direction may a direction that traverses the first direction.

During battery expanding (or swelling), the battery cell 30 may expand (or swell) in a direction toward the backside panel 70. When this occurs, the battery protection circuit 100 (or swelling detection circuit) may detect (or determine) that the first conductive member 90 has contacted the second conductive member 80. The battery protection circuit 100 and/or other components of the electronic device may perform any of a number of functions/operations to help avoid any further expanding or swelling of the battery cell 30. For example, components of the electronic device 1 may recalibrate the full capacity of the battery (or battery cell) so that recharging may only be to a lower capacity to reduce risk of further expansion/swelling. Additionally, another way to avoid further expanding or swelling is to decrease a rate of battery discharge, reduce processor frequency/device or system load and/or reduce need to increase frequency of charging.

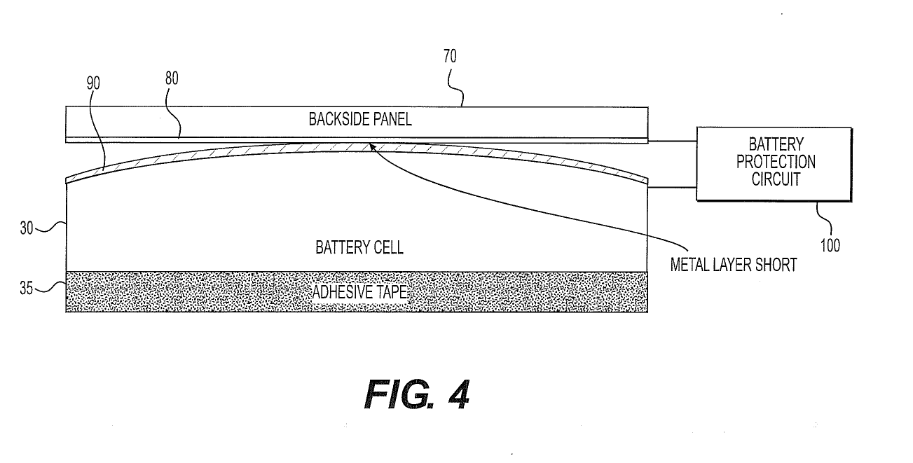

FIG. 4 shows an example of battery expansion detection according to an example embodiment. Other embodiments and configurations may also be provided. The battery expansion detection may occur within an electronic device, for example.

FIG. 4 shows an example of the battery cell 30 that has expanded (or swelled) such that the first conductive member 90 contacts the second conductive member 80. As is shown, this may cause a metal layer short that may be detected (or determined) by the battery protection circuit 100 (or swelling detection circuit). The metal layer short may be an electrical short between the first conductive member 90 and the second conductive member 80. The battery protection circuit 100 and/or other components of the electronic device 1 may perform any of a number of functions/operations to help avoid any further expansion/swelling and/or perform operations to protect other components.

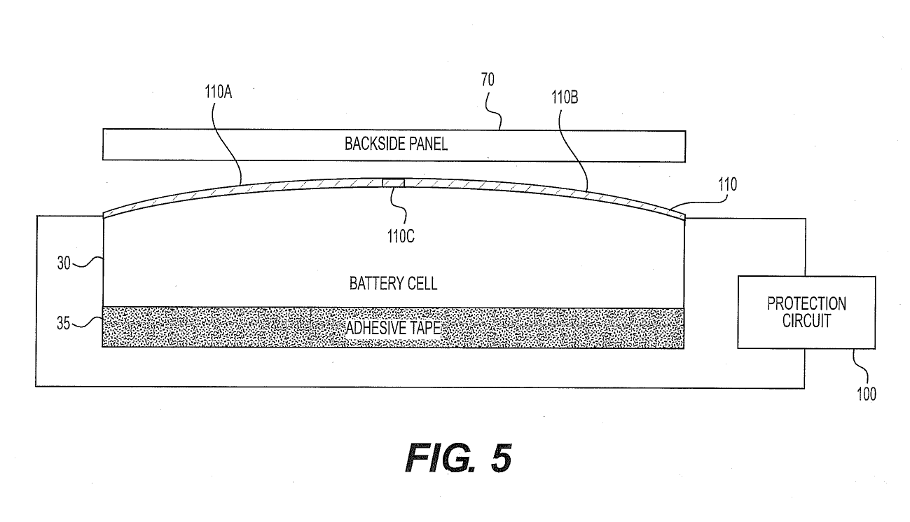

FIG. 5 is a side view showing battery expansion detection according to an example embodiment. Other embodiments and configurations may also be provided. The battery expansion detection may occur within an electronic device, for example.

FIG. 5 shows a conductive member 110 on a top surface of the battery cell 30. The conductive member 110 may be a conductive layer on the top surface of the battery cell 30. The protection circuit 100 may be coupled at two points (or two opposite ends) of the conductive member 110. FIG. 5 shows an example in which the battery cell 30 has swelled (or expanded) such that the conductive member 110 may break due to brittleness. This may cause an open-circuit between the two points (or two opposite ends) of the conductive member 110. The protection circuit 100 may detect an open circuit based on the conductive member 110. For example, when the conductive member 110 physically breaks during expansion (or swelling) of the battery cell 30, then the protection circuit 100 may detect the open circuit.

In another embodiment, the conductive member 110 may include two separate conductive members, namely a first member portion 110A and a second member portion 110B. The first member portion 110A may be electrically connected to the second member portion 110B by a conductive connector 110C. The conductive connector 110C may break when the battery cell 30 expands or swells. This may cause an open-circuit between the first member position 110A and the second member position 110B. The protection circuit 100 may detect (or determine) the open circuit based on the conductive connector 110C (which may be part of the conductive member 110). The protection circuit may detect the battery cell expansion based on an electrical disconnection between the first member position and the second member position.

The battery protection circuit 100 (or swelling detection circuit) may be logic, at least a portion of which is hardware, to perform the above described detecting, sensing or determining, such as change of impedance, change of resistance, electrical short circuit and/or open circuit.

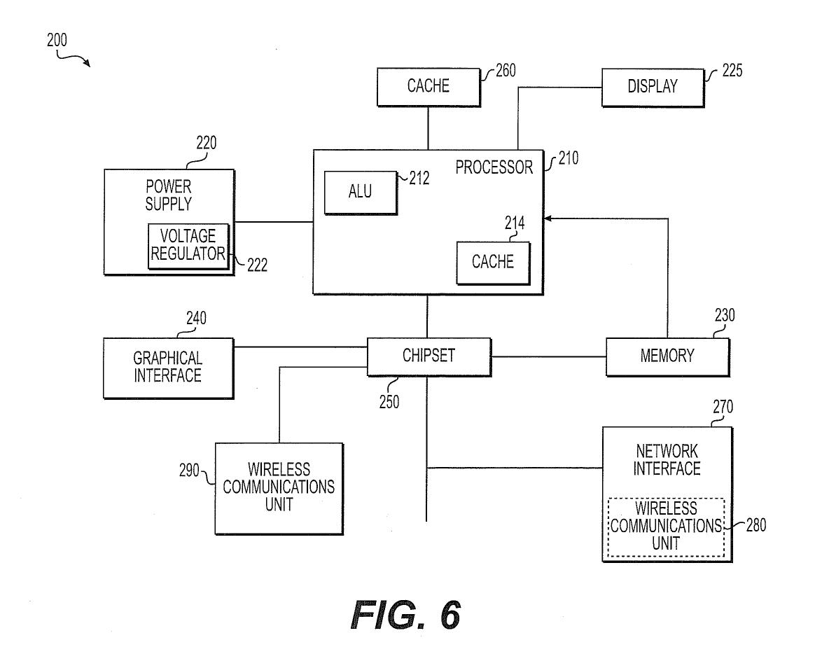

FIG. 6 shows an electronic system according to an example embodiment. Other embodiments and configurations may also be provided.

More specifically, FIG. 6 shows a system 200 that includes a processor 210, a power supply 220, a display 225 and a memory 230, which may be a random access memory, for example. The processor 210 may include an arithmetic logic unit 212 and an internal cache 214, for example. The processor 210 may perform operations by using received instructions, such as instructions received via a computer-readable medium.

The above-described features may be provided within the electrical system 200 shown in FIG. 6. For example, the battery cell may be provided as part of the power supply 220 to provide power to any of the electronic components. Any of the other described features may also be provided, such as but not limited to, a first conductive member, a second conductive member, and a protection circuit.

In at least one embodiment, the battery cell (and other features) may be part of the electronic system to provide power to other components.

The voltage regulator 222 may be part of the power supply 210.

The system 200 may also include a graphical interface 240, a chipset 250, a cache 260, a network interface 270 and a wireless communication unit 280, which may be incorporated within the network interface 270. Alternatively or additionally, a wireless communications unit 290 may be coupled to the processor 210, and a direct connection may exist between the memory 230 and the processor 210.

The processor 210 may be a central processing unit, a microprocessor or any other type of processing or computing circuit and may be included on a chip die with all or any combination of the remaining features, or one or more of the remaining features may be electrically coupled to the microprocessor die through known connections and interfaces. Also, the connections that are shown are merely illustrative as other connections between or among the elements depicted may exist depending, for example, on chip platform, functionality, or application requirements.

In at least one embodiment, a computer-readable medium may store a program for controlling the circuitry or logic to stop (or reduce) further charging or discharging based on the sensed characteristics of at least one of the first conductive member or the second conductive member. The circuitry or logic may control the expanding (or swelling) of the battery cell. The program may be stored in a memory, which for example, may be internal or external to the electronic device of the electronic system. In at least one embodiment, the program may be part of a control algorithm for controlling operations of the battery charger (related to charging of the battery cell).

Instructions or code executed by a controller (or processor), for example, may be provided to a memory from a machine-accessible medium, or an external storage device accessible via a remote connection (e.g. over a network via an antenna and/or network interface) providing access to one or more electronically-accessible media, etc. A machine-accessible medium (or computer-readable medium) may include any mechanism that provides (i.e., stores and/or transmits) information in a form readable by a machine (e.g., a computer). For example, a machine-accessible medium may include random access memory (RAM), read-only memory (ROM), magnetic or optical storage medium, flash memory devices, electrical, optical, acoustical or other form of propagated signals (e.g., carrier waves, infrared signals, digital signals), etc. In alternative embodiments, hard-wired circuitry may be used in place of or in combination with the instructions or code, and thus the embodiments are not limited to any specific combination of hardware circuitry and software instructions.

The program may include code or instructions to perform any of the operations or functions performed in embodiments previously discussed above.

The following examples pertain to further embodiments.

Example 1 is an apparatus comprising: a panel to cover at least a portion of a battery cell, a first conductive member on the battery cell; and a protection circuit to detect battery cell expansion based on the first conductive member.

In Example 2, the subject matter of Example 1 can optionally include a second conductive member on the panel.

In Example 3, the subject matter of Example 1 and Example 2 can optionally include that the first conductive member is a first conductive line, and the second conductive member is a second conductive line.

In Example 4, the subject matter of Example 1 and Example 2 can optionally include that the first conductive member extends in a first direction, and the second conductive member extends in a second direction.

In Example 5, the subject matter of Example 1 and Example 2 can optionally include that at least one of the first conductive member and the second conductive member is a metal sheet.

In Example 6, the subject matter of Example 1 and Example 2 can optionally include that at least one of the first conductive member and the second conductive member is a metal deposition layer.

In Example 7, the subject matter of any one of Examples 2-6 can optionally include that the protection circuit to detect an electrical short between the first conductive member and the second conductive member.

In Example 8, the subject matter of any one of Examples 2-6 can optionally include that the protection circuit to detect an impedance change of at least one of the first conductive member and the second conductive member.

In Example 9, the subject matter of Example 1 and Example 8 can optionally include a battery charger to decrease a charging of the battery cell when the protection circuit detects the impedance change.

In Example 10, the subject matter of any one of Examples 2-6 can optionally include that the protection circuit to detect a resistance change of at least one of the first conductive member and the second conductive member.

In Example 11, the subject matter of any one of Examples 2-6 can optionally include that the protection circuit to decrease charging of the battery cell or discharging of the battery cell when the protection circuit detects a change of at least one of the first conductive member and the second conductive member.

In Example 12, the subject matter of Example 1 can optionally include that the panel is a backside panel of the apparatus.

In Example 13, the subject matter of any one of Examples 2-6 can optionally include that the protection circuit to detect an open-circuit based on the first conductive member.

In Example 14, the subject matter of Example 1 can optionally include that the first conductive member includes a first member portion, a second member portion and a conductive connector between the first member portion and the second member portion.

In Example 15, the subject matter of Example 1 and Example 13 can optionally include that the protection circuit to detect the battery cell expansion based on an electrical disconnection between the first member portion and the second member portion.

Example 16 is a system comprising: a memory, a processor to perform an operation, a display to display an image, and a protection circuit to detect expansion of a battery cell based on a change of at least a first conductive member.

In Example 17, the subject matter of Example 16 can optionally include that the first conductive member to be on the battery cell.

In Example 18, the subject matter of Example 16 can optionally include a panel to cover at least a portion of the battery cell.

In Example 19, the subject matter of Example 16 and Example 18 can optionally include that a second conductive member to be on the panel.

In Example 20, the subject matter of Example 16 and Example 19 can optionally include that the protection circuit to detect the first conductive member to contact the second conductive member.

In Example 21, the subject matter of Example 16 and Example 19 can optionally include that the first conductive member is a first conductive line, and the second conductive member is a second conductive line.

In Example 22, the subject matter of Example 16 and Example 19 can optionally include that the first conductive member extends in a first direction, and the second conductive member extends in a second direction.

In Example 23, the subject matter of Example 16 and Example 19 can optionally include that at least one of the first conductive member and the second conductive member is a metal sheet.

In Example 24, the subject matter of Example 16 and Example 19 can optionally include that at least one of the first conductive member and the second conductive member is a metal deposition layer.

In Example 25, the subject matter of any one of Examples 19-24 can optionally include that the protection circuit to detect an electrical short between the first conductive member and the second conductive member.

In Example 26, the subject matter of any one of Examples 19-24 can optionally include that the protection circuit to detect an impedance change of at least one of the first conductive member and the second conductive member.

In Example 27, the subject matter of Example 26 can optionally include a battery charger to decrease a charging of the battery cell when the protection circuit detects the impedance change.

In Example 28, the subject matter of any one of Examples 19-24 can optionally include that the protection circuit to detect a resistance change of at least one of the first conductive member and the second conductive member.

In Example 29, the subject matter of any one of Examples 19-24 can optionally include that the protection circuit to decrease charging of the battery cell when the protection circuit detects a change of at least one of the first conductive member and the second conductive member.

In Example 30, the subject matter of Example 16 and Example 19 can optionally include that the panel is a backside panel of the system.

In Example 31, the subject matter of any one of Examples 19-24 can optionally include that the protection circuit to detect an open-circuit based on the first conductive member.

In Example 32, the subject matter of Example 16 can optionally include that the first conductive member includes a first member portion, a second member portion and a conductive connector between the first member portion and the second member portion.

In Example 33, the subject matter of Example 16 and Example 32 can optionally include that the protection circuit to detect expansion of the battery cell based on an electrical disconnection between the first member portion and the second member portion.

Example 34 is an electronic device comprising: a panel on at least a portion of a battery cell, a first conductive member on the battery cell, and means for detecting battery cell expansion based on the first conductive member.

In Example 35, the subject matter of Example 34 can optionally include a second conductive member on the panel.

In Example 36, the subject matter of Example 34 and Example 35 can optionally include that the first conductive member is a first conductive line, and the second conductive member is a second conductive line.

In Example 37, the subject matter of Example 34 and Example 35 can optionally include that the first conductive member extends in a first direction, and the second conductive member extends in a second direction.

In Example 38, the subject matter of Example 34 and Example 35 can optionally include that at least one of the first conductive member and the second conductive member is a metal sheet.

In Example 39, the subject matter of Example 34 and Example 35 can optionally include that at least one of the first conductive member and the second conductive member is a metal deposition layer.

In Example 40, the subject matter of any one of Examples 35-39 can optionally that the means for detecting to detect an electrical short between the first conductive member and the second conductive member.

In Example 41, the subject matter of any one of Examples 35-39 can optionally that the means for detecting to detect an impedance change of at least one of the first conductive member and the second conductive member.

In Example 42, the subject matter of Example 35 and Example 41 can optionally means for charging a battery cell and for decreasing a charging the battery cell when the means for detecting detects the impedance change.

In Example 43, the subject matter of any one of Examples 35-39 can optionally that the protection circuit to detect a resistance change of at least one of the first conductive member and the second conductive member.

In Example 44, the subject matter of any one of Examples 35-39 can optionally that the means for detecting to decrease charging of the battery cell when the means for detecting detects a change of at least one of the first conductive member and the second conductive member.

In Example 45, the subject matter of Example 34 can optionally include that the panel is a backside panel of the electronic device.

In Example 46, the subject matter of Example 34 can optionally include that the means for detecting to detect an open-circuit based on the first conductive member.

In Example 47, the subject matter of Example 34 can optionally include that the first conductive member includes a first member portion, a second member portion and a conductive connector between the first member portion and the second member portion.

In Example 48, the subject matter of Example 34 and Example 47 can optionally include that the means for detecting to detect the battery cell expansion based on an electrical disconnection between the first member portion and the second member portion.

Example 49 is an electronic device comprising: a battery port to receive a battery cell, and means for detecting expansion of the battery cell based on a change of at least a first conductive member.

In Example 50, the subject matter of Example 49 can optionally include that the first conductive member to be on the battery cell.

In Example 51, the subject matter of Example 49 can optionally include a panel on at least a portion of the battery cell.

In Example 52, the subject matter of Example 49 and Example 51 can optionally include that a second conductive member to be on the panel.

In Example 53, the subject matter of Example 49 and Example 52 can optionally include that the means for detecting to detect the first conductive member to contact the second conductive member.

In Example 54, the subject matter of Example 49 and Example 52 can optionally include that the first conductive member is a first conductive line, and the second conductive member is a second conductive line.

In Example 55, the subject matter of Example 49 and Example 52 can optionally include that the first conductive member extends in a first direction, and the second conductive member extends in a second direction.

In Example 56, the subject matter of Example 49 and Example 52 can optionally include that at least one of the first conductive member and the second conductive member is a metal sheet.

In Example 57, the subject matter of Example 49 and Example 52 can optionally include that at least one of the first conductive member and the second conductive member is a metal deposition layer.

In Example 58, the subject matter of any one of Examples 52-57 can optionally that the means for detecting to detect an electrical short between the first conductive member and the second conductive member.

In Example 59, the subject matter of any one of Examples 50-57 can optionally that the means for detecting to detect an impedance change of at least one of the first conductive member and the second conductive member.

In Example 60, the subject matter of Example 49 and Example 59 can optionally include means for charging a battery cell and for decreasing a charging of the battery cell when the means for detecting detects the impedance change.

In Example 61, the subject matter of any one of Examples 50-57 can optionally that the means for detecting to detect a resistance change of at least one of the first conductive member and the second conductive member.

In Example 62, the subject matter of any one of Examples 50-57 can optionally that the means for detecting to decrease charging of the battery cell when a change of at least one of the first conductive member and the second conductive member is detected.

In Example 63, the subject matter of Example 49 and Example 52 can optionally include that the panel is a backside panel of the electronic device.

In Example 64, the subject matter of Example 49 can optionally include that the means for detecting to detect an open-circuit based on the first conductive member.

In Example 65, the subject matter of Example 49 can optionally include that the first conductive member includes a first member portion, a second member portion and a conductive connector between the first member portion and the second member portion.

In Example 66, the subject matter of Example 49 and Example 65 can optionally include that the means for detecting to detect expansion of the battery cell based on an electrical disconnection between the first member portion and the second member portion.

Example 67 is an apparatus comprising: a panel to cover at least a portion of a battery cell, a first conductive member on the battery cell, and logic, at least a portion of which is hardware, to detect battery cell expansion based on the first conductive member.

In Example 68, the subject matter of Example 67 can optionally include a second conductive member on the panel.

In Example 69, the subject matter of Example 67 and Example 68 can optionally include that the first conductive member is a first conductive line, and the second conductive member is a second conductive line.

In Example 70, the subject matter of Example 67 and Example 68 can optionally include that the first conductive member extends in a first direction, and the second conductive member extends in a second direction.

In Example 71, the subject matter of Example 67 and Example 68 can optionally include that at least one of the first conductive member and the second conductive member is a metal sheet.

In Example 72, the subject matter of Example 67 and Example 68 can optionally include that at least one of the first conductive member and the second conductive member is a metal deposition layer.

In Example 73, the subject matter of any one of Examples 68-72 can optionally that the logic to detect an electrical short between the first conductive member and the second conductive member.

In Example 74, the subject matter of any one of Examples 68-72 can optionally that the logic to detect an impedance change of at least one of the first conductive member and the second conductive member.

In Example 75, the subject matter of Example 67 and Example 74 can optionally include that a battery charger to decrease a charging of the battery cell when the logic detects the impedance change.

In Example 76, the subject matter of any one of Example 68-72 can optionally that the logic to detect a resistance change of at least one of the first conductive member and the second conductive member.

In Example 77, the subject matter of any one of Examples 68-72 can optionally that the logic to decrease charging of the battery cell or discharging of the battery cell when the logic detects a change of at least one of the first conductive member and the second conductive member.

In Example 78, the subject matter of Example 67 can optionally include that the panel is a backside panel of the apparatus.

In Example 79, the subject matter of any one of Examples 68-72 can optionally that the logic to detect an open-circuit based on the first conductive member.

In Example 80, the subject matter of Example 67 can optionally include that the first conductive member includes a first member portion, a second member portion and a conductive connector between the first member portion and the second member portion.

In Example 81, the subject matter of Example 67 and Example 80 can optionally include that the logic to detect the battery cell expansion based on an electrical disconnection between the first member portion and the second member portion.

Any reference in this specification to “one embodiment,” “an embodiment,” “example embodiment,” etc., means that a particular feature, structure, or characteristic described in connection with the embodiment is included in at least one embodiment. The appearances of such phrases in various places in the specification are not necessarily all referring to the same embodiment. Further, when a particular feature, structure, or characteristic is described in connection with any embodiment, it is submitted that it is within the purview of one skilled in the art to affect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An apparatus comprising:
a panel to cover at least a portion of a battery cell;
a first conductive member on the battery cell; and
a protection circuit to detect battery cell expansion based on the first conductive member.

2. The apparatus of claim 1, further comprising a second conductive member on the panel.

3. The apparatus of claim 2, wherein the first conductive member is a first conductive line, and the second conductive member is a second conductive line.

4. The apparatus of claim 2, wherein the protection circuit to detect an electrical short between the first conductive member and the second conductive member.

5. The apparatus of claim 2, wherein the protection circuit to detect an impedance change of at least one of the first conductive member and the second conductive member.

6. The apparatus of claim 2, wherein the protection circuit to detect a resistance change of at least one of the first conductive member and the second conductive member.

7. The apparatus of claim 1, wherein the first conductive member includes a first member portion, a second member portion and a conductive connector between the first member portion and the second member portion.

8. The apparatus of claim 7, wherein the protection circuit to detect the battery cell expansion based on an electrical disconnection between the first member portion and the second member portion.

9. A system comprising:
a memory;
a processor to perform an operation;
a display to display an image; and
a protection circuit to detect expansion of a battery cell based on a change of at least a first conductive member.

10. The system of claim 9, wherein the first conductive member to be on the battery cell.

11. The system of claim 9, further comprising:
a panel to cover at least a portion of the battery cell.

12. The system of claim 11, further comprising a second conductive member to be on the panel.

13. The system of claim 12, wherein the protection circuit to detect the first conductive member to contact the second conductive member.

14. The system of claim 12, wherein the protection circuit to detect an electrical short between the first conductive member and the second conductive member.

15. The system of claim 12, wherein the protection circuit to detect an impedance change of at least one of the first conductive member and the second conductive member.

16. The system of claim 9, wherein the first conductive member includes a first member portion, a second member portion and a conductive connector between the first member portion and the second member portion.

17. The system of claim 16, wherein the protection circuit to detect expansion of the battery cell based on an electrical disconnection between the first member portion and the second member portion.

18. An electronic device comprising:
a panel on at least a portion of a battery cell;
a first conductive member on the battery cell; and
means for detecting battery cell expansion based on the first conductive member.

19. The electronic device of claim 18, further comprising a second conductive member on the panel.

20. The electronic device of claim 18, wherein the means for detecting to detect an electrical short between the first conductive member and the second conductive member.
